(19) United States
(12) Patent Application Publication
(10) Pub. No.: US 2023/0402998 A1
(43) Pub. Date: Dec. 14, 2023

(54) COMPARATOR MODULE AND OSCILLATOR USING THE SAME

(71) Applicant: NUVOTON TECHNOLOGY CORPORATION, Hsinchu City (TW)

(72) Inventors: CHENG-TAO LI, Zhubei City (TW); PING-WEN LAI, Zhubei City (TW)

(21) Appl. No.: 17/979,520

(22) Filed: Nov. 2, 2022

(30) Foreign Application Priority Data
Jun. 13, 2022 (TW) 111121823

(51) Int. Cl. H03K 3/0233; H03K 5/24; H03K 3/03

(52) U.S. Cl. CPC H03K 3/0233; H03K 3/03; H03K 5/2481

(57) ABSTRACT

A comparator module for an oscillator is disclosed. The comparator module has a function provided by two independent comparators that are combined together to share the same bias current source, so that an operation current of the oscillator may be reduced, and the circuit area and power consumption may be effectively reduced. Further, compared to the conventional design that one of the two comparators compares a first voltage with a reference voltage and the other one of the two comparators compares a second voltage with the reference voltage and the time points at which the first voltage and the second voltage are a logic high level are different, three transistors of the disclosed comparator module are designed into two equivalent differential pairs and share a bias current source.

### CROSS-REFERENCE TO RELATED APPLICATION

This application claims the priority from TW Patent Application No. 111121823, filed on Jun. 13, 2022, and all contents of such TW Patent Applications are included in the present disclosure.

### BACKGROUND

### 1. Field of the Invention

The present disclosure relates to a comparator module for an oscillator, in particular to, a comparator module that integrates two independent comparators by making the two comparators share part of a circuit.

### 2. Description of the Related Art

Oscillators are widely used in various circuits, and are especially used in digital sequential circuits which require clock signals. In daily life, most electronic products have digital sequential circuits. Thus, these electronic products also have oscillators. Further, at present, users not only expect that electronic products can be light, thin and short, but also expect that electronic products can save energy and electricity.

Referring to FIG. 1, which is a block diagram of a conventional oscillator. A conventional oscillator 1 comprises two comparators 11 and 12, an output stage circuit 13 and two bias current sources 14 and 15. A positive input end of the comparator 11 is configured to receive a first voltage V_{C1}, and a negative input end of the comparator 11 is configured to receive a reference voltage V_{REF}. A bias end of the comparator 11 is electrically connected to the bias current source 14 to provide a bias current for biasing. An output end of the comparator 11 is configured to output a first comparison result signal VS to one of input ends of the output stage circuit 13. A positive end of the comparator 12 is configured to receive a second voltage V_{C2}, and a negative end of the comparator 12 is configured to receive the reference voltage V_{REF}. A bias end of the comparator 12 is electrically connected to the bias current source 15 to provide the bias current for biasing. An output end of the comparator 12 outputs a second comparison result signal VR to the other input end of the output stage circuit 13. The output stage circuit 13 is configured to generate a voltage V_{OSC} based on the first comparison result signal VS and the second comparison result signal VR. Moreover, the output stage circuit 13 can be implemented by a set-reset latch (SR latch).

The referent voltage V_{REF} is a constant voltage, while the first voltage V_{C1} and the second voltage V_{C2} are capacitor voltages formed by charging and discharging a capacitor through a charging/discharging circuit. Therefore, the first comparison result signal VS and the second comparison result signal VR may be changed from a logic low level to a logic high level based on a predetermined period. Further, the first comparison result signal VS and the second comparison result signal VR can be changed to the logic low level after lasting the logic high level for a period of time. When the first comparison result signal VS is changed from the logic low level to the logic high level, the output stage circuit 13 outputs the voltage V_{OSC} with the logic high level. As well, when the second comparison result signal VR is changed from the logic low level to the logic high level, the output stage circuit 13 outputs the voltage V_{OSC} with the logic low level. Consequently, the voltage V_{OSC} is a periodically changing oscillation signal.

The conventional oscillator 1 uses the two independent comparators 11 and 12. Actually, the comparators 11 and 12 operate alternatively. When one of the comparators 11, 12 is operating, other one of the comparator 11, 12 is in a waiting state, that is, the time points at which the first voltage V_{C1} and the second voltage V_{C2} are greater than the reference voltage VREF are different, and usually, when one of the two capacitors corresponding to the first voltage V_{C1} is charged, the other of the two capacitors corresponding to the second voltage V_{C2} is discharged. However, the other one of the comparator 11 and 12 is in the waiting state, so that it still unnecessarily consumes bias current. Accordingly, in addition to the technical problem of larger circuit area, the oscillator 1 of the related art also has the technical problems of energy consumption and power consumption.

### SUMMARY

An embodiment of the present disclosure provides a comparator module for an oscillator. The comparator module comprises a bias current generating circuit, a bias current source, a first transistor, a second transistor and a third transistor. The bias current generating circuit has a first end, a second end and a third end, and the bias current generating circuit is configured to receive a supply voltage to generate a bias current. The bias current source is is configured to accept the bias current. The first transistor is electrically connected between the first end and the bias current source, and the first transistor is configured to receive a reference voltage. The second transistor is electrically connected between the second end and the bias current source, and the second transistor is configured to receive a first voltage. The third transistor is electrically connected between the third end and the bias current source, and the third transistor is configured to receive a second voltage. The first transistor is turned on by using the reference voltage as a bias voltage, so as to make a first sub-current of the bias current flow to the bias current source. Also, one of the second transistor and the third transistor is turned on based on the reference voltage, the first voltage and the second voltage, so as to make a second sub-current of the bias current flow through the one of the second transistor and the third transistor which is turned on to the bias current source. Further, the second end of the bias current generating circuit is configured to generate a first comparison result signal, and the third end of the bias current generating circuit is configured to generate a second comparison result signal.

An embodiment of the present disclosure also provides an oscillator. The oscillator comprises the preceding comparator module and an output stage circuit. The output stage circuit is configured to receive the first comparison result signal and the second comparison signal to generate an oscillation signal.

As stated above, compare with the related art, the comparator module and the oscillator using the comparator module of the embodiments of the present disclosure have less circuit area, lower operating current consumption and lower power consumption. As well, the present disclosure conforms the current trends of energy saving, carbon saving, and lightness, thinness and shortness of electronic products.

To further understand the technology, means, and effects of the present disclosure, reference may be made by the detailed description and drawing as follows. Accordingly, the purposes, features and concepts of the present disclosure can be thoroughly and concretely understood. However, the following detail description and drawings are only used to reference and illustrate the implementation of the present disclosure, and they are not used to limit the present disclosure.

### BRIEF DESCRIPTION OF THE DRAWINGS

The drawings are provided to make the persons with ordinary knowledge in the field of the art further understand the present disclosure, and are incorporated into and constitute a part of the specification of the present disclosure. The drawings illustrate demonstrated embodiments of the present disclosure, and are used to explain the principal of the present disclosure together with the description of the present disclosure.

FIG. 1 is a block diagram of an oscillator of a related art;

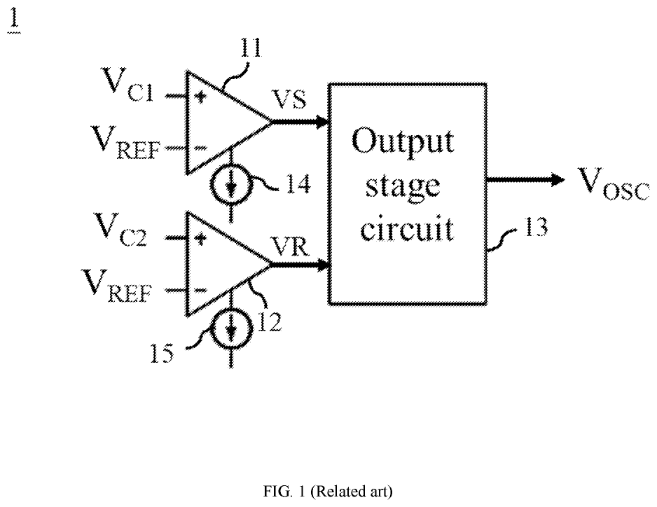

FIG. 2 is a block diagram of an oscillator according to an embodiment of the present disclosure;

FIG. 3 is a circuit diagram of a comparator module according to an embodiment of the present disclosure; and

FIG. 4 is a circuit diagram of a reference voltage/current generating circuit, a first voltage generating circuit and a second voltage generating circuit according to an embodiment of the present disclosure.

### DESCRIPTION OF THE PREFERRED EMBODIMENTS

The embodiments of the present disclosure are described in detail as reference, and the drawings of the present disclosure are illustrated. In the case of possibility, the element symbols are used in the drawings to refer to the same or similar components. In addition, the embodiment is only one approach of the implementation of the design concept of the present disclosure, and the following multiple embodiments are not intended to limit the present disclosure.

An embodiment of the present disclosure provides a comparator module for an oscillator. The comparator module has the function of combining two independent comparators. Also, a circuit design of the two independent comparators shares the same bias current source, so that an operating current of the oscillator can be reduced. Thus, the circuit area and power consumption can be effectively reduced. Further, two comparators in the related art compare a first voltage with a reference voltage and compare the second voltage with the reference voltage respectively. As well, the time points at which the first voltage and the second voltage are a logic high level are different. Therefore, two equivalent differential pairs can be designed with three transistors, and the three transistors share a bias current source. At one of the time points, the two transistors receiving the first voltage and the reference voltage form one of the differential pairs, and compete to use the shared bias current based on a voltage received by a gate of each transistor, so there is an effect of a comparator. At the other one of the time points, the two transistors receiving the second voltage and the reference voltage form the other one of the differential pairs, and use the shared bias current based on a voltage received by a gate of each transistor, so there is an effect of another comparator.

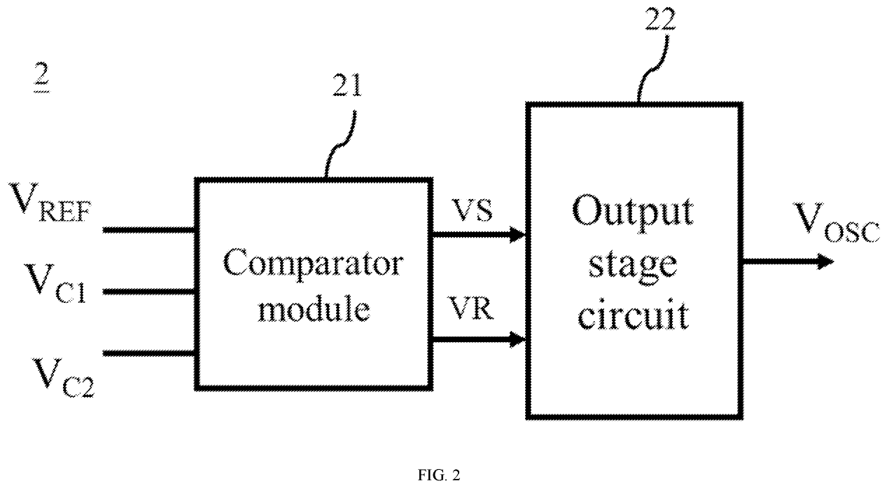

Firstly, referring to FIG. 2, FIG. 2 is a block diagram of an oscillator according to an embodiment of the present disclosure. An oscillator 2 comprises a comparator module 21 and an output stage circuit 22. The comparator module 21 is configured to receive a first voltage V_{C1}, a second voltage V_{C2} and a reference voltage V_{REF}. The time points at which the first voltage V_{C1} and the second voltage V_{C2} are the logic high level are different because the comparator module 21 is configured in the oscillator 2. Further, the first voltage V_{C1} is a voltage (a triangle wave signal itself) at one end of a first capacitor that charges and discharges the first capacitor. The second voltage V_{C2} is a voltage (a triangle wave signal itself) at one end of a second capacitor and configured to charge and discharge the second capacitor.

When the first capacitor is charged or discharged and the first voltage V_{C1} is greater than the reference voltage V_{REF}, a first comparison result signal VS output by the comparator module 21 is the logic high level. On the contrary, when the first voltage V_{C1} is lower than the reference voltage V_{REF}, the first comparison result signal VS output by the comparator module 21 is at a logic low level. When the second capacitor is charged or discharged and the second voltage V_{C2} is greater than the reference voltage, a second comparison result signal VR output by the comparator module 21 is at the logic high level. On the contrary, when the second voltage V_{C2} is lower than the reference voltage, the second comparison result signal VR output by the comparator module 21 is at the logic low level. The first comparison result signal VS and the second comparison result signal VR does not be the logic high level at the same time.

The output stage circuit 22 is configured to output a voltage V_{OSC} based on the first comparison result signal VS and the second comparison result signal VR. When the first comparison result signal VS is changed from the logic low level to the logic high level, the voltage V_{OSC} output by the output stage circuit 22 is the logic high level. As well, when the second comparison result signal VR is changed from the logic low level to the logic high level, the voltage V_{OSC} output by the output stage circuit 22 is the logic low level. The first comparison result signal VS and the second comparison result signal VR are periodically changed from the logic low level to the logic high level, so the voltage V_{OSC} is an oscillation signal. Additionally, the output stage circuit 22 may be implemented by a set-reset latch (SR latch). A set input end of the set-reset latch is configured to receive the first comparison result signal VS, and a reset input end of the set-reset latch is configured to receive the second comparison result signal VR. Moreover, an output end of the set-reset latch is configured to output the oscillation signal (the voltage V_{OSC}).

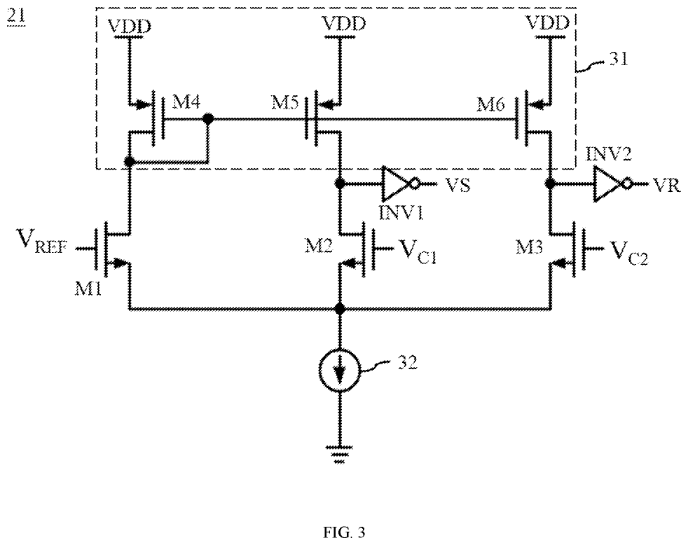

Next, referring to FIG. 2 and FIG. 3, FIG. 3 is a circuit diagram of a comparator module according to an embodiment of the present disclosure. The comparator module 21 of

FIG. 2 may be implemented by the structure of FIG. 3. The comparator module 21 comprises a bias current generating circuit 31, a bias current source 32 and three transistors (a first transistor M1, a second transistor M2 and a third transistor M3, respectively). The bias current generating circuit 31 has a first end, a second end and a third end. The first transistor M1 is electrically connected between the first end of the bias current generating circuit 31 and the bias current source 32. The first transistor M1 is configured to receive the reference voltage V_{REF}. The second transistor M2 is electrically connected between the second end of the bias current generating circuit 31 and the bias current source 32. The second transistor M2 is configured to receive the first voltage V_{C1}. The third transistor M3 is electrically connected between the third end of the bias current generating circuit 31 and the bias current source 32. The third transistor M3 is configured to receive the second voltage V_{C2}.

The bias current generating circuit 31 is configured to receive a supply voltage VDD to generate a bias current (comprising a first bias sub-current flowing through the first transistor M1 and a second bias sub-current flowing through the second transistor M2 or the third transistor M3). The bias current source 32 is configured to accept the bias current (i.e., the bias current source 32 receives the first bias sub-current and the second bias sub-current.). Due to the action of the reference voltage V_{REF}, the first transistor M1 is turned on, so that the first bias sub-current of the bias current flows to the bias current source 32. When the first voltage V_{C1} is greater than the reference voltage V_{REF}, the second transistor M2 is turned on, so that the second bias sub-current of the bias current flows through the second transistor M2 to the bias current source 32. When the second voltage V_{C2} is greater than the reference voltage V_{REF}, the third transistor M3 is turned on, so that the second bias sub-current of the bias current flows through the third transistor M3 to the bias current source 32. As mentioned above, the time points at which the first voltage V_{C1} and the second voltage V_{C2} are the logic high level are different. Thus, the time points when the second transistor M2 and the third transistor M3 are turned on are different. Besides, the second end of the bias current generating circuit 31 is configured to generate the first comparison result signal VS, and the third end of the bias current generating circuit 31 is configured to generate the second comparison result signal VR.

In an embodiment of the present disclosure, the comparator module 21 further comprises a first inverter INV1 and a second inverter INV2. The first inverter INV1 is electrically connected to the second end of the bias current generating circuit 31. The first inverter INV1 is configured to use an inverted signal of a voltage signal at the second end of the bias current generating circuit 31 to output the first comparison result signal VS. The second inverter INV2 is electrically connected to the third end of the bias current generating circuit 31. The second inverter INV2 is configured to use an inverted signal of a voltage signal at the third end of the bias current generating circuit 31 to output the second comparison result signal VR. The first inverter INV1 and the second inverter INV2 are not necessary components of the comparator module 21. In other embodiments, buffers are used to replace, or the first inverter INV1 and the second inverter INV2 are removed directly.

Each of the first transistor Ml, the second transistor M2 and the third transistor M3 is an NMOS transistor. A gate of the first transistor M1 is configured to receive the reference voltage V_{REF}, a drain of the first transistor M1 is electrically connected to the first end of the bias current generating circuit 31, and a source of the first transistor M1 is electrically connected to the bias current source 32. A gate of the second transistor M2 is configured to receive the first voltage V_{C1}, a drain of the second transistor M2 is electrically connected to the second end of the bias current generating circuit 31, and a source of the second transistor M2 is electrically connected to the bias current source 32. A gate of the third transistor M3 is configured to receive the second voltage V_{C2}, a drain of the third transistor M3 is electrically connected to the third end of the bias current generating circuit 31, and a source of the third transistor M3 is electrically connected to the bias current generating circuit 32. In this embodiment, the second voltage is a low voltage (for example, a ground voltage) and the third transistor M3 is not turned on when the first voltage V_{C1} rises. The first voltage V_{C1} is the low voltage (for example, the ground voltage) and the second transistor M2 is not turned on when the second voltage V_{C2} rises.

The bias current generating circuit 31 comprises a fourth transistor M4, a fifth transistor M5 and a sixth transistor M6. Each of the fourth transistor M4, the fifth transistor M5 and the sixth transistor M6 is a PMOS transistor. A source of the fourth transistor M4, a source of the fifth transistor M5, and a source of the sixth transistor M6 are configured to receive the supply voltage VDD. A drain of the fourth transistor M4 is electrically connected to the first end of the bias current generating circuit 31, a drain of the fifth transistor M5 is electrically connected to the second end of the bias current generating circuit 31, and a drain of the sixth transistor M6 is electrically connected to the third end of the bias current generating circuit 31. A gate of the fourth transistor M4 is electrically connected to the drain of the fourth transistor M4, a gate of the fifth transistor M5 and a gate of the sixth transistor M6.

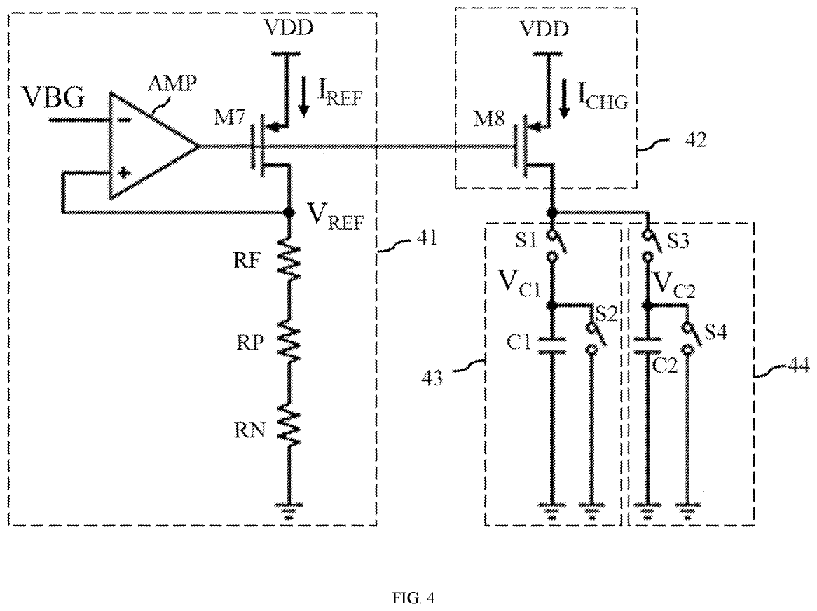

Referring to FIG. 2, FIG. 3 and FIG. 4, FIG. 4 is a circuit diagram of a reference voltage/current generating circuit, a first voltage generating circuit and a second voltage generating circuit according to an embodiment of the present disclosure. The oscillator 2 further comprises a reference voltage/current generating circuit 41, a charge current generating circuit 42, a first voltage generating circuit 43 and a second voltage generating circuit 44. The reference voltage/current generating circuit 41 is electrically connected to the first transistor M1 of the comparator 21. As well, the reference voltage/current generating circuit 41 is configured to provide the reference voltage V_{REF} and a reference current I_{REF}. The charge current generating circuit 42 is electrically connected to the reference voltage/current generating circuit 41. The charge current generating circuit 42 is configured to generate a charge current I_{CHG}.

The first voltage generating circuit 43 is electrically connected to the charge current generating circuit 42. The first voltage generating circuit 43 is configured to receive the charge current I_{CHG} based on a first control signal and a second control signal to charge or discharge a first capacitor C1 of the first voltage generating circuit 43, so as to provide the first voltage V_{C1} to one end of the first capacitor C1. The second voltage generating circuit 44 is electrically connected to the charge current generating circuit 42. The second voltage generating circuit 44 is configured to receive the charge current I_{CHG} based on the first control signal and the second control signal to charge or discharge a second capacitor C2 of the second voltage generating circuit 44, so as to provide the second voltage V_{C2} to one end of the second capacitor C2. Furthermore, when the first capacitor C1 is charged, the second capacitor C2 is discharged. When the first capacitor C1 is discharged, the second capacitor C2 is charged.

Further, the reference voltage/current generating circuit 41 and the charge current generating circuit 42 may be implemented in the following manner. The reference voltage/current generating circuit 41 comprises an operational amplifier AMP, a seventh transistor M7 and at least one resistor (a plurality of resistors RF, RP and RN connected in series, and one end of the resistor RN is electrically connected to the low voltage, such as the ground voltage). The charge current generating circuit 42 comprises an eighth transistor M8. Each of the seventh transistor M7 and the eighth transistor M8 is a PMOS transistor. A negative input end of the operational amplifier AMP is configured to receive a bandgap voltage VBG. A gate of the seventh transistor M7 and a gate of the eighth transistor M8 are electrically connected to an output end of the operational amplifier AMP. A source of the seventh transistor M7 and a source of the eighth transistor M8 are configured to receive the supply voltage VDD. A drain of the seventh transistor M7 is electrically connected to a positive input end of the operational amplifier AMP and one end of the resister RF. The end of the resister RF is configured to provide the reference voltage V_{REF}. A drain of the eighth transistor M8 is electrically connected to the first voltage generating circuit 43 and the second voltage generating circuit 44. The drain of the eighth transistor M8 is configured to provide the charge current I_{CHG}.

The first voltage generating circuit 43 and the second voltage generating circuit 44 may be implemented in the following manner. The first voltage generating circuit 43 comprises the first capacitor C1, a switch S2 and a switch S3, and the second voltage generating circuit 44 comprises the second capacitor C2, a third switch S3 and a fourth switch S4. The first switch S1 is electrically connected between the charge current generating circuit 42 and the first capacitor C1. The first switch S1 is configured to determine whether to be turned on based on the first control signal, so as to provide the charge current I_{CHG} to charge the first capacitor C1. Also, the second switch S2 is electrically connected between the first capacitor C1 and the low voltage (such as the ground voltage). The second switch S2 is configured to determine whether to be turned on based on the second control signal, so as to discharge the first capacitor C1. The third switch S3 is electrically connected between the charge current generating circuit 42 and the second capacitor C2. The third switch S3 is configured to determine whether to be turned on based on the second control signal, so as to provide the charge current I_{CHG} to charge the second capacitor C2. As well, the fourth switch S4 is electrically connected between the second capacitor C2 and the low voltage. The fourth switch S4 is configured to determine whether to be turned on based on the first control signal, so as to discharge the second capacitor C2. Further, the second control signal may be an inverted first control signal.

In conclusion, the comparator module for the oscillator provided by the embodiments of the present disclosure integrates two independent comparators to reduce a plurality of transistors, and the two independent comparators share the same bias current source. Accordingly, compare with the related art, the comparator module and the oscillator using the comparator module of the embodiments of the present disclosure have less circuit area, lower operating current consumption and lower power consumption. Furthermore, it is in line with the current trend of energy saving, carbon saving and lightness, thinness and shortness of electronic products.

It should be understood that the examples and the embodiments described herein are for illustrative purpose only, and various modifications or changes in view of them will be suggested to those skilled in the art, and will be included in the spirit and scope of the application and the appendix with the scope of the claims.

What is claimed is:

1. A comparator module for an oscillator, comprising:
a bias current generating circuit, having a first end, a second end and a third end, and configured to receive a supply voltage to generate a bias current;
a bias current source, configured to accept the bias current;
a first transistor, electrically connected between the first end and the bias current source, and configured to receive a reference voltage;
a second transistor, electrically connected between the second end and the bias current source, and configured to receive a first voltage; and
a third transistor, electrically connected between the third end and the bias current source, and configured to receive a second voltage;
wherein the first transistor is turned on by the reference voltage as a bias voltage, to make a first bias sub-current of the bias current flow to the bias current source, and one of the second transistor and the third transistor is turned on based on the reference voltage, the first voltage and the second voltage, to make a second bias sub-current of the bias current flow through the one of the second transistor and the third transistor which is turned on to the bias current source;
wherein the second end is configured to generate a first comparison result signal, and the third end is configured to generate a second comparison result signal.

2. The comparator module according to claim 1, further comprising:
a first inverter, electrically connected to the second end, and configured to output the first comparison result signal; and
a second inverter, electrically connected to the third end, and configured to output the second comparison result signal.

3. The comparator module according to claim 1, wherein each of the first transistor, the second transistor and the third transistor is an NMOS transistor;
wherein a gate of the first transistor is configured to receive the reference voltage, a drain of the first transistor is electrically connected to the first end, a source of the first transistor is electrically connected to the bias current source, a gate of the second transistor is configured to receive the first voltage, a drain of the second transistor is electrically connected to the second end, a source of the second transistor is electrically connected to the bias current source, a gate of the third transistor is configured to receive the second voltage, a drain of the third transistor is electrically connected to the third end, and a source of the third transistor is electrically connected to the bias current source.

4. The comparator module according to claim 3, wherein the bias current generating circuit comprises a fourth transistor, a fifth transistor and a sixth transistor;
wherein each of the fourth transistor, the fifth transistor and the sixth transistor is a PMOS transistor;
wherein a source of the fourth transistor, a source of the fifth transistor and a source of the sixth transistor are configured to receive the supply voltage, a drain of the fourth transistor is electrically connected to the first end, a drain of the fifth transistor is electrically connected to the second end, a drain of the sixth transistor is electrically connected to the third end, and a gate of the fourth transistor is electrically connected to the drain of the fourth transistor, a gate of the fifth transistor and a gate of the sixth transistor.

5. An oscillator, comprising:
a comparator module, comprising:
a bias current generating circuit, having a first end, a second end and a third end, and configured to receiving a supply voltage to generate a bias current;
a bias current source, configured to accept the bias current;
a first transistor, electrically connected between the first end and the bias current source, and configured to receive a reference voltage;
a second transistor, electrically connected between the third end and the bias current source, and configured to receive a first voltage; and
a third transistor, electrically connected between the second end and the bias current source, and configured to receive a second voltage;
wherein the first transistor is turned on by the reference voltage as a bias voltage, to make a first bias sub-current of the bias current flows to the bias current source, and one of the second transistor and the third transistor is turned on based on the reference voltage, the first voltage and the second voltage, to make a second bias sub-current of the bias current flow through the one of the second transistor and the third transistor which is turned on to the bias current source;
wherein the second end is configured to generate a first comparison result signal, and the third end is configured to generate a second comparison result signal; and
an output stage circuit, configured to receive the first comparison result signal and the second comparison result signal to generate an oscillation signal.

6. The oscillator according to claim 5, wherein the comparator module further comprises:
a first inverter, electrically connected to the second end, and configured to output the first comparison result signal; and
a second inverter, electrically connected to the third end, and configured to output the second comparison result signal.

7. The oscillator according to claim 5, wherein each of the first transistor, the second transistor and the third transistor is an NMOS transistor;
wherein a gate of the first transistor is configured to receive the reference voltage, a drain of the first transistor is electrically connected to the first end, a source of the first transistor is electrically connected to the bias current source, a gate of the second transistor is configured to receive the first voltage, a drain of the second transistor is electrically connected to the second end, a source of the second transistor is electrically connected to the bias current source, a gate of the third transistor is configured to receive the second voltage, a drain of the third transistor is electrically connected to the third end, and a source of the third transistor is electrically connected to the bias current source.

8. The oscillator according to claim 7, wherein the bias current generating circuit comprises a fourth transistor, a fifth transistor and a sixth transistor;
wherein each of the fourth transistor, the fifth transistor and the sixth transistor is a PMOS transistor;
wherein a source of the fourth transistor, a source of the fifth transistor and a source of the sixth transistor are configured to receive the supply voltage, a drain of the fourth transistor is electrically connected to the first end, a drain of the fifth transistor is electrically connected to the second end, a drain of the sixth transistor is electrically connected to the third end, and a gate of the fourth transistor is electrically connected to the drain of the fourth transistor, a gate of the fifth transistor and a gate of the sixth transistor.

9. The oscillator according to claim 5, wherein the output stage circuit is a set-reset (SR) latch;
wherein a set-input end of the set-reset latch is configured to receive the first comparison result signal, a reset-input end of the set-reset latch is configured to receive the second comparison result signal, and an output end of the set-reset latch is configured to output the oscillation signal.

10. The oscillator according to claim 5, further comprising:
a reference voltage/current generating circuit, electrically connected to the first transistor, and configured to provide the reference voltage and a reference current;
a charge current generating circuit, electrically connected to the reference voltage/current generating circuit, and configured to generate a charge current based on the reference current;
a first voltage generating circuit, electrically connected to the charge current generating circuit, and configured to receive the charge current based on a first control signal and a second control signal, to charge or discharge a first capacitor of the first voltage generating circuit, to provide the first voltage at one end of the first capacitor; and
a second voltage generating circuit, electrically connected to the charge current generating circuit, and configured to receive the charge current based on the first control signal and the second control signal, to charge or discharge a second capacitor of the second voltage generating circuit, to provide the second voltage at one end of the second capacitor.

11. The oscillator according to claim 10, wherein when the first capacitor is charged, the second capacitor is discharged; and
when the first capacitor is discharged, the second capacitor is charged.

12. The oscillator according to claim 10, wherein the reference voltage/current generating circuit comprises an operational amplifier, a seventh transistor and a resistor, and
the charge current generating circuit comprises an eighth transistor;
wherein each of the seventh transistor and the eighth transistor is a PMOS transistor;
wherein a negative input end of the operational amplifier is configured to receive a bandgap voltage, a gate of the seventh transistor and a gate of the eighth transistor are electrically connected to an output end of the operational amplifier, a source of the seventh transistor and a source of the eighth transistor are configured to receive the supply voltage, a drain of the seventh transistor is electrically connected to a positive input end of the operational amplifier and one end of the resistor, the end of the resistor is configured to provide the reference voltage, a drain of the eighth transistor is electrically connected to the first voltage generating circuit and the second voltage generating circuit, and the drain of the eighth transistor is configured to provide the charge current.

13. The oscillator according to claim 10, wherein the first voltage generating circuit comprises the first capacitor, a first switch and a second switch, and
the second voltage generating circuit comprises the second capacitor, a third switch and a fourth switch;
wherein the first switch is electrically connected between the charge current generating circuit and the first capacitor, and the first switch is turned on based on the first control signal, to provide the charge current to charge the first capacitor;
the second switch is electrically connected between the first capacitor and a low voltage, and is turned on based on the second control signal, to discharge the first capacitor;
the third switch is electrically connected between the charge current generating circuit and the second capacitor, and is turned on based on the second control signal, to provide the charge current to charge the second capacitor; and
the fourth switch is electrically connected between the second capacitor and the low voltage, and is turned on based on the first control signal, to discharge the second capacitor.
